(19) United States
(12) Patent Application Publication
(10) Pub. No.: US 2024/0321647 A1
(43) Pub. Date: Sep. 26, 2024

(54) SEMICONDUCTOR DEVICES WITH INTEGRATED TEST AREAS

(71) Applicant: Woflspeed, Inc., Durham, NC (US)

(72) Inventors: In-Hwan Ji, Apex, NC (US); Rahul R. Potera, Apex, NC (US); Neal Oldham, Apex, NC (US); Qi Zhou, Raleigh, NC (US); Casey Burkhart, Raleigh, NC (US)

(21) Appl. No.: 18/125,655

(22) Filed: Mar. 23, 2023

(51) Int. Cl. H01L 21/66; H01J 49/00; H01L 29/06; H01L 29/16; H01L 29/872

(52) U.S. Cl. CPC H01L 22/12; H01J 49/0004; H01L 29/0619; H01L 29/1608; H01L 29/872

(57) ABSTRACT

A semiconductor device includes a semiconductor layer including an active area, a first implanted region within the active area at a surface of the semiconductor layer, and an integrated test area in the semiconductor layer. The integrated test area includes a second implanted region in the semiconductor layer.

### BACKGROUND

The present disclosure relates to semiconductor device structures and in particular to power semiconductor devices including silicon carbide Schottky diodes, metal-oxide semiconductor field effect transistors (MOSFETs), and bipolar junction transistors (BJTs).

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group Ill nitrides (e.g., 3.36 eV for GaN at room temperature). These materials may have higher electric field breakdown strengths and higher electron saturation velocities than GaAs and Si.

One important application for wide bandgap semiconductors such as silicon carbide is in Schottky diodes.

A Schottky diode, also known as Schottky barrier diode, is a semiconductor diode formed by the junction of a semiconductor with a metal. The metal-semiconductor junction (instead of a semiconductor-semiconductor junction as in conventional PN-junction diodes) in a Schottky diode creates a Schottky barrier. The metal side acts as the anode, and an n-type semiconductor acts as the cathode of the diode. When sufficient forward voltage is applied to overcome the Schottky barrier of the metal-semiconductor junction, current flows through the device in the forward direction. When a reverse voltage is applied, a depletion region is formed in the semiconductor, obstructing current flow.

Compared to a conventional PN-junction diode, a Schottky diode has a low forward voltage drop and a very fast switching action.

An important difference between a PN-junction diode and a Schottky diode is the reverse recovery time (tᵣᵣ), which it the time it takes of the diode to switch from a conducting (forward biased) state to a non-conducting (reverse biased) state. In the conducting state, a conventional PN-junction diode injects minority carriers into the diffusion region on the N-side of the junction where they recombine with majority carriers after diffusion. The reverse recovery time of a PN-junction is primarily limited by the diffusion capacitance of minority carriers accumulated in the diffusion region during the conducting state.

In contrast, a Schottky diode is a unipolar or “majority carrier” device that does not rely on minority carrier injection. Rather, in the conducting state, majority carriers (electrons in the case of an n-type semiconductor layer) are injected across the junction. Thus, switching a Schottky diode from a conducting to a non-conducting state does not require time for recombination of the injected carriers. Rather, the switching speed of a Schottky diode is only limited by the junction capacitance of the device.

Silicon carbide Schottky diodes are the rectifiers of choice in advanced power electronics at 650V and above, primarily because they achieve fast switching speeds with much lower leakage current and capacitance than silicon-based Schottky diodes.

In addition to Schottky diodes, other types of semiconductor devices such as MOSFETs and BJTs can benefit from the material properties of silicon carbide.

### SUMMARY

A semiconductor device according to some embodiments includes a semiconductor layer including an active area and an edge termination area outside the active area, a first implanted region within the active area at a surface of the semiconductor layer, and an integrated test area in the semiconductor layer. The integrated test area includes a second implanted region in the semiconductor layer.

The integrated test area may be within the active area or outside the active area.

The semiconductor layer may have a first conductivity type and the first and second implanted regions have a second conductivity type opposite the first conductivity type,

The semiconductor device may further include an anode contact on the semiconductor layer in the active area. The anode contact contacts the integrated test area.

The integrated test area may have peripheral dimensions selected to permit a destructive material test to be performed on the semiconductor layer within the integrated test area

The active area may include a first plurality of junction shielding regions in the semiconductor layer. The semiconductor layer may have a first conductivity type, and the first plurality of junction shielding regions have a second conductivity type opposite the first conductivity type. The anode contact contacts the semiconductor layer, the first plurality of junction shielding regions and the integrated test area.

The semiconductor layer may have a first conductivity type, and the integrated test areas may have the first conductivity type or a second conductivity type opposite the first conductivity type.

The active area may have a generally rectangular shape, and the test active area may be located near a center of the active area.

The active area may have a generally rectangular shape, and the test active area may be located near a corner of the active area.

The active area may have a generally rectangular shape, and the test area may be located near a middle of a side of the active area.

The integrated test area may have an area of at least about 2500 μm².

The integrated test area may be square in shape. A side length of the integrated test area may be from about 50 μm to about 150 μm.

The semiconductor device may include a Schottky diode device, a bipolar junction transistor, or a metal-oxide semiconductor device.

The semiconductor device may include a metal layer on the semiconductor layer, wherein the metal layer contacts the first implanted region, and an insulating layer on the second implanted region, wherein the second implanted region is insulated from the metal layer by the insulating layer.

The semiconductor may include an isolation region in the semiconductor layer, wherein the isolation region surrounds the second implanted region. The isolation region may include a trench in the semiconductor layer or a semi-insulating region in the semiconductor layer.

A method according to some embodiments includes forming a singulated semiconductor device, wherein the singulated semiconductor device includes a semiconductor layer including an active area and an edge termination area outside the active area, a plurality of implanted regions within the active area at a surface of the semiconductor layer, and an integrated test area in the semiconductor layer. The integrated test area includes an implanted region in the semiconductor layer. The method further includes performing secondary ion mass spectrometry (SIMS) analysis on the integrated test area of the singulated semiconductor device.

The semiconductor layer may have as first conductivity type, and the integrated test area may have the first conductivity type.

The semiconductor layer may have as first conductivity type, and the integrated test area may have a second conductivity type opposite the first conductivity type.

The integrated test area may have peripheral dimensions selected to permit a destructive material test to be performed on the semiconductor layer within the integrated test area

The semiconductor layer may have a first conductivity type and the integrated test region may have a second conductivity type opposite the first conductivity type. The active area may include a first plurality of junction shielding regions in the semiconductor layer, the first plurality of junction shielding regions having the second conductivity type. The anode contact contacts the semiconductor layer, the first plurality of junction shielding regions and the integrated test area.

The semiconductor layer may include an n-type semiconductor material, and the integrated test area may include a p-type semiconductor material.

The active area may have a generally rectangular shape, and the test active area may be located near a center of the active area.

The active area may have a generally rectangular shape, and the test active area may be located near a corner of the active area.

The active area may have a generally rectangular shape, and the test area may be located near a middle of a side of the active area.

The integrated test area may have an area of at least about 2500 μm2.

The integrated test area may be square, rectangular, circular, or oval in shape.

A side length of the integrated test area may be from about 50 μm to about 150 μm.

The semiconductor device may include a Schottky diode device, a bipolar junction transistor, or a metal-oxide semiconductor device.

The SIMS analysis may be performed after a failure of the device during operation of the device.

### BRIEF DESCRIPTION OF THE DRAWINGS

FIG. 1 illustrates a Schottky diode according to some embodiments.

FIG. 2A illustrates an apparatus for performing secondary ion mass spectrometry (SIMS).

FIG. 2B illustrates a SIMS profile generated by secondary ion mass spectrometry.

FIGS. 3A and 3B are plan views of a Schottky diode in accordance with some embodiments.

FIGS. 4A, 4B, and 4C are cross sectional illustration of a portion of a Schottky diode in accordance with various embodiments.

FIGS. 5, 6 and 7 are plan views of Schottky diodes in accordance with various embodiments.

FIG. 8 is schematic diagram of a semiconductor device including an integrated test structure according to further embodiments.

FIG. 9 is a flowchart of operations for testing a semiconductor device according to some embodiments.

### DETAILED DESCRIPTION OF EMBODIMENTS

Embodiments of the inventive concepts will now be described in connection with the accompanying drawings.

Silicon carbide Schottky diodes are well suited for use in advanced power electronics at voltages of 650V and above, primarily because they achieve fast switching speeds with much lower leakage current and capacitance than silicon Schottky diodes. In power supply boost convertors, a SiC Schottky diode is required to carry a surge current of about 10-15× the rated current for a short interval of several milliseconds. So-called MPS (Merged PN-Schottky) diodes accomplish this by merging islands of P-N junctions into the Schottky diode so that at high forward currents, the P-N junction can turn on, which enables conductivity modulation of the drift layer and allows the device to conduct surge current at lower voltages than conventional Schottky diodes.

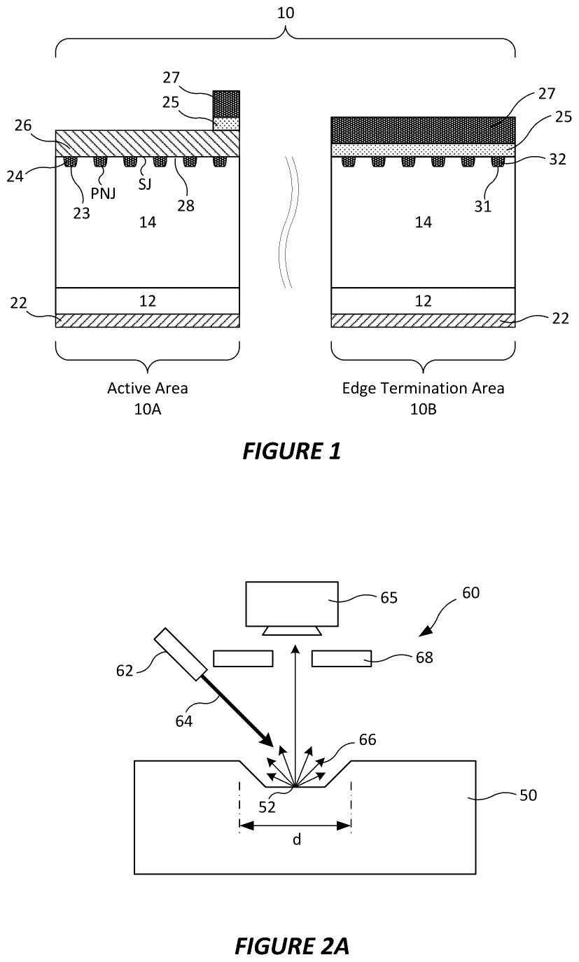

An MPS Schottky diode 10 is illustrated in cross-section in FIG. 1. The Schottky diode 10 includes an active area 10A and an edge termination area 10B (also called a junction termination region, or simply a termination region) that is outside the active area 10A. Although the active area 10A and the edge termination area 10B are shown in FIG. 1 as separate regions for ease of illustration, it will be appreciated that they are part of the same device.

An n-silicon carbide epitaxial layer 14 is formed on a silicon carbide substrate 12. In this context, “n-” refers to the conductivity type of the silicon carbide material, and indicates that it is lightly doped with n-type dopants. A semiconductor substrate, layer or region can be doped with impurities that cause the material to have an excess of either positively charged (p-type) or negatively charged (n-type) charge carriers, which defines the conductivity type of the material. A “+” or “−” sign is used to indicate that a particular region or layer of the semiconductor material is more or less heavily doped than another region or layer. For example, materials described as “n-” are more lightly doped, with lower concentrations of n-type dopants than an n-type layer, while materials described as “n+” are more heavily doped, with higher concentrations of n-type dopants than an n-type layer.

A metal anode contact 26 is formed on the surface of the silicon carbide epitaxial layer 14 opposite the substrate 12. The anode contact 26 forms a Schottky barrier junction SJ with the silicon carbide epitaxial layer 14.

At the surface of the silicon carbide epitaxial layer 14, a plurality of p+ junction shielding regions 24 are formed at the surface of the silicon carbide epitaxial layer 14. The p+ junction shielding regions 24 may be formed by ion implantation to form P-N junctions PNJ with the silicon carbide epitaxial layer 14. A cathode ohmic contact 22 is formed on the back side of the substrate 12. The anode contact 26 forms ohmic contact to the p+ junction shielding regions 24. Although described in terms of a device including an n-type epitaxial layer 14 and p-type junction shielding regions 24, it will be appreciated that in some embodiments the conductivity types may be reversed, i.e., a p-type epitaxial layer with n-type shielding regions.

The Schottky barrier junction SJ between the anode contact 26 and the silicon carbide epitaxial layer 14, which is formed on exposed regions 28 of the silicon carbide epitaxial layer 14 between the p+ junction shielding regions 24, has a lower barrier energy than the P-N junctions PNJ between the p+ junction shielding regions 24 and the silicon carbide epitaxial layer 14. This allows the Schottky barrier junction SJ to turn on before the P-N junctions PNJ in the forward biased (conducting) state. Conversely, in the reverse biased (non-conducting) state, the Schottky barrier junction SJ is shielded from high electric fields by the depletion region formed at the interface of the P-N junctions PNJ and the silicon carbide epitaxial layer 14.

In the edge termination area 10B, a plurality of floating guard rings 32 (also called equipotential rings or field rings) are formed in respective regions 31 at the surface of the silicon carbide epitaxial layer 14. The guard rings 32 may comprise implanted p+ regions in the silicon carbide epitaxial layer 14. A silicon nitride passivation layer 25 is formed over the edge termination area 10B and extends onto the anode contact 26 in the active area 10A. A protective layer 27 of a material such as polyimide is formed on the silicon nitride passivation layer 25.

A problem that can occur during manufacture of a device, such as a Schottky diode, is that the performance of the Schottky junction under surge current conditions may vary depending on implant dose, depth and activation conditions of the p-type implant that is used to form the p-type junction shielding regions 24. To monitor this issue with respect to the implant and activation anneal, a process control monitoring (PCM) structure may be used. A PCM structure is typically a separate die that is formed on a wafer on which production devices are formed. The PCM structure may be analyzed using secondary ion mass spectrometry (SIMS) to determine the properties of the p-type implant. SIMS is a surface analysis technique that uses a focused ion beam to sputter (remove) material from a sample surface and ionize the ejected atoms. The resulting ions are then mass-analyzed to provide information about the chemical composition of the sample surface.

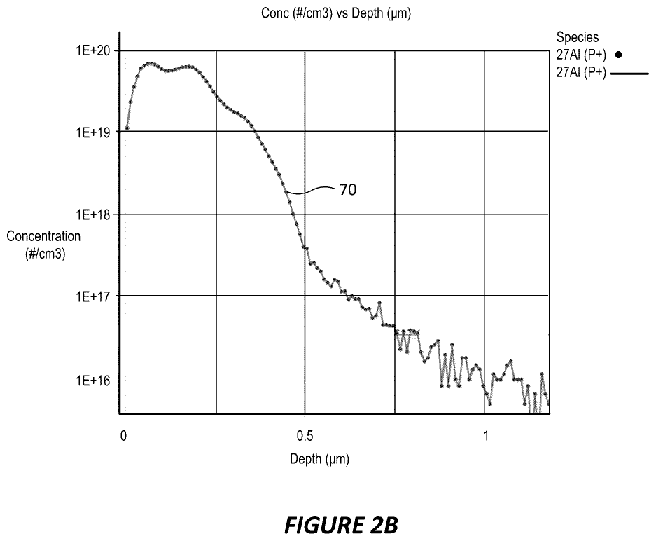

An apparatus 60 for performing SIMS analysis is shown in FIG. 2A. Note that in FIG. 2A, the size of the sample 50 relative to the SIMS apparatus 60 is exaggerated for purposes of illustration. As shown in FIG. 2A, the apparatus 60 includes a mass spectrometer 65, a primary ion source 62 and an extraction lens 68. The apparatus 60 is used to analyze the material composition of a sample 50, which may, for example, be an epitaxial layer structure such as found in a Schottky diode device 10. To perform the SIMS analysis, a focused beam 64 of primary ions is generated by the primary ion source 62 and directed at a target location 52 on the sample 50. When the primary ion beam 64 strikes the sample 50, secondary ions 66 that formed part of the material structure of the sample 50 are physically ejected from the sample 50 and collected through the extraction lens 68 by the mass spectrometer 65.

As can be seen in FIG. 2A, SIMS analysis physically sputters away secondary ions 66 from the sample 50, so that as the analysis proceeds, secondary ions 66 present at increasing depths of the sample are ejected and analyzed. The mass spectrometer 65 counts the secondary ions 66 ejected from the sample 50, and generates a graph that shows the concentration of analyzed ions in the sample 50 as a function of depth. The graph generated by SIMS analysis may be referred to as a “depth profile.”

An example of a depth profile 70 generated by SIMS analysis is shown in FIG. 2B. In particular, the graph in FIG. 2B shows a depth profile 70 of aluminum ions (which are p-type dopants in SiC) in a sample under analysis. The depth profile is a graph of concentration (in cm⁻³) of Al ions in the sample as a function of depth in microns (μm). In the example shown in FIG. 2B, Al ions have a maximum concentration of about 7E19 cm⁻³ at a depth of about 0.1 to 0.2 μm, and the p-type implanted region extends to a depth of about 0.5 μm beneath the surface of the sample. By analyzing the depth profile of the p-type implants that form the p-type junction shielding regions 24 in a Schottky diode 10, it is possible to verify the expected surge current performance of the device.

Referring again to FIG. 2A, even though the primary ion beam 64 is focused on a small target location 52, the primary ion beam 64 causes secondary ions within a relatively large area (shown as width d in FIG. 2A) to be ejected from the sample 50. For that reason, it may be difficult to perform an accurate SIMS analysis on the relatively small p-type junction shielding regions 24 in a Schottky diode 10. Thus, to perform an accurate SIMS analysis, a test structure may be formed in a PCM device on a wafer on which multiple production devices are formed. The test structure may have a large test area in which SIMS can be accurately performed. However, analysis of a test structure cannot provide the information about the actual p-type implantation characteristics of the other devices on the wafer due, for example, to process variations across the wafer.

Some embodiments described herein provide a semiconductor device structure including a built-in test area on which a material analysis test such as SIMS can performed on the device itself, rather than having to analyze a separate test structure and infer the properties of the device from the analysis of the test structure.

Some embodiments described herein may thereby enable a manufacturer to identify problems with ion implantation by enabling material analysis to be performed on a production die. This allows the properties of an individual production die to be characterized, which may reduce the likelihood of failure of the resulting device.

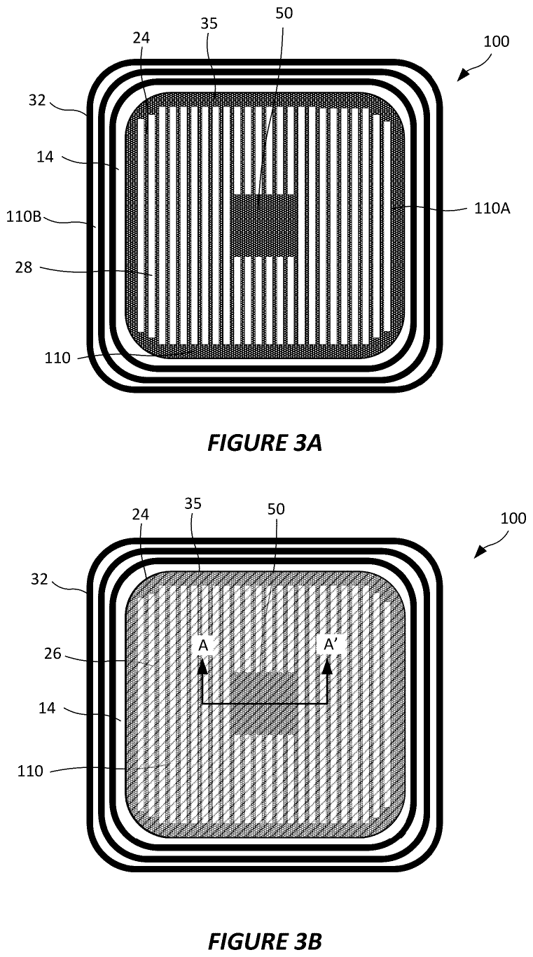

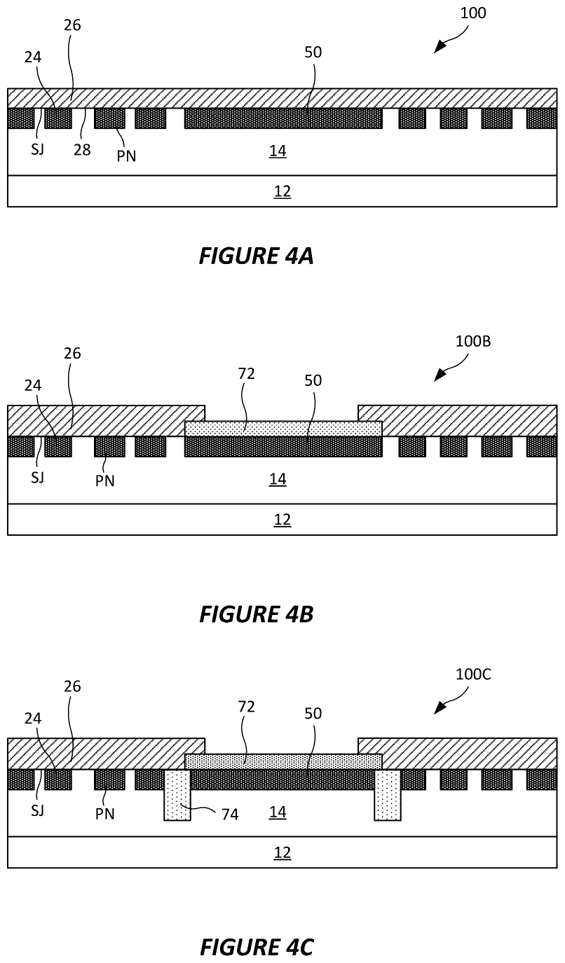

FIGS. 3A and 3B are plan views of a singulated Schottky diode 100 including a main Schottky diode device 110 and an integrated test area 50 according to some embodiments, and FIG. 4A is a cross sectional view taken along line A-A′ of FIG. 3B. FIG. 3A illustrates the Schottky diode 100 without Schottky metallization for clarity of illustration, and FIGS. 3B and 4A illustrate the Schottky diode 100 with Schottky metallization. In an example embodiment, the Schottky diode 100 may be formed in SiC and have overall dimensions of about 5 mm×5 mm, and may have a reverse voltage blocking rating of 1200V and a forward current rating of 50A, although the inventive concepts described herein are applicable to devices having other dimensions and/or voltage/current ratings.

“Singulated” means that the semiconductor device has been separated from other similar semiconductor devices formed on the same substrate. For example, in semiconductor manufacturing, many devices are typically formed on the same semiconductor or wafer, and then the devices are singulated, or separated from one another, prior to packaging. Singulation may be accomplished, for example, by sawing the wafer or substrate between devices.

Referring to FIG. 3A, the Schottky diode 100 includes a semiconductor layer 14 including an active area 110A that is inside an edge termination area 110B. The active area 110A may have a generally rectangular shape, although other shapes are possible. The edge termination area 110B, which is outside the active area 110A, includes a plurality of concentric floating guard rings 32. However, it will be appreciated that different edge termination structures may be provided in the main edge termination area 110B.

An implanted well region 35 is formed within the main active area 110A. The implanted well region 35 may comprise a p+ implanted region that is patterned to form a plurality of p+ junction shielding regions 24 that form the second junctions PNJ described above in connection with FIG. 1. Still referring to FIG. 3A, an integrated test area 50 is formed within the active area 110A (i.e. inside the periphery of the edge termination area 110B). The integrated test area 50 is formed as an implanted region in which the p+ junction shielding regions 24 are not formed. The integrated test area 50 may be formed via ion implantation in a same ion implantation process as is used to form the p+ junction shielding regions 24, so that the integrated test area 50 has substantially the same doping profile as the p+ junction shielding regions 24.

Referring to FIGS. 3B and 4A, an anode contact 26 is formed on the epitaxial layer 14 in the active area 110A including over the integrated test area 50. The anode contact 26 forms a Schottky junction SJ with the silicon carbide layer epitaxial 14 in exposed regions of the silicon carbide epitaxial layer 14 between the p+ junction shielding regions 24, and forms ohmic contact to the p+ junction shielding regions 24.

Prior to formation of the anode contact 26, a material analysis, such as SIMS analysis, may be performed on the die in the integrated test area 50 to verify that the implant doping profile of p-type dopants into the epitaxial layer 14 is within acceptable limits. This may help to ensure that the surge current performance of the device 100 will meet design requirements.

Referring again to FIG. 3A, the integrated test area 50 may be formed as a generally rectangular implanted region in the epitaxial layer 14. The integrated test area has peripheral dimensions selected to permit a destructive material test, such as a SIMS analysis, to be performed on the semiconductor layer 14 within the integrated test area 50. In particular, the integrated test area 50 may have an area of at least about 2500 μm². For example, the integrated test area 50 may have an area of about 2500 μm² to about 25,000 μm².

In particular embodiments, each side of the integrated test area 50 may have a length of about 50 to about 150 μm. Thus, in some embodiments, the integrated test area 50 may have dimensions of about 50 μm×50 μm up to about 150 μm×150 μm. In particular embodiments, the integrated test area 50 may have dimensions of about 100 μm×100 μm.

The size of the active area 110A determines the surge current capability of the device, where a device with a larger active area 110A will have a larger surge current capability. For a given size of the integrated test area 50, the percentage of area in the active area 110A occupied by the integrated test area 50 will be different. For example, for an integrated test area 50 having dimensions of 100 μm×100 μm, the percentage of the active area 110A occupied by the integrated test area 50 is shown in Table 1.

TABLE 1
Percentage of Active Area Occupied by Integrated Test Area

| Surge Current | Active Area | Test Area | Percent |
|---|---|---|---|
| Capability | (μm²) | (μm²) | (%) |
| 50 A | 19080000 | 10000 | 0.052411 |
| 20 A | 7632000 | 10000 | 0.131027 |
| 10 A | 3816000 | 10000 | 0.262055 |

As seen in Table 1, only a negligible portion of the active area may be occupied by the integrated test area in some embodiments.

The inclusion of the integrated test area 50 within the active area 110A may result in slightly reduced forward current capability due to the reduction in area in which the Schottky junction SJ is formed. However, it may also slightly increase the surge current carrying capability of the device.

In some embodiments, the integrated test area 50 may be at least partially isolated from the remaining portion of the active area of the device. For example, as shown in FIG. 4B, a Schottky diode structure 100B includes an integrated test area 50. The integrated test area 50 is insulated from the anode contact 26 by an insulating layer 72 on the integrated test area 50. The insulating layer 72 may be formed, for example of silicon nitride, silicon dioxide, polyimide, or any other suitable insulating material. The anode contact 26 may extend onto and/or over the insulating layer 72.

Referring to FIG. 4C, a Schottky diode structure 100C according to some embodiments includes an isolation region 74 in the semiconductor epitaxial layer 14. The isolation region 74 surrounds the integrated test area 50. The integrated test area 50 may thereby be at least partially isolated from the remaining part of the active area of the device 100C via the isolation region 74. The isolation region 74 may be a trench in the semiconductor epitaxial layer 14 or may be formed as an implanted region that is implanted with ions such as C or Fe to cause the isolation region 74 to become semi-insulating. Although the Schottky diode structure 100C includes both an insulating layer 72 and an isolation region 74, a Schottky diode structure according to some embodiments may include the isolation region 74 and not include the insulating layer 72 on the integrated test area 50.

In FIGS. 3A and 3B, the integrated test area 50 is shown as being in the center of the active area 110A. It is presently believed that placing the integrated test area 50 in the center of the active area 110A will have the smallest impact on the performance characteristics of the device under both forward and reverse bias conditions, as it should not cause unbalanced current flow under forward operating conditions or affect the reverse blocking capability of the device.

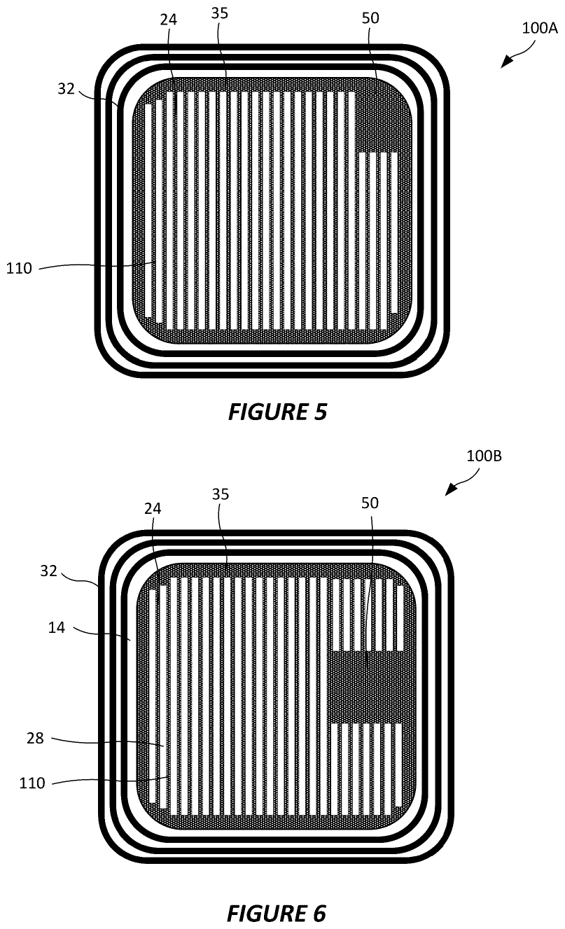

It will be appreciated, however, that the integrated test area 50 may be formed in various places within the active area 110A of the Schottky diode structure 100 depending on design requirements. For example, FIG. 5 illustrates a further embodiment of a Schottky diode structure 100A in which the integrated test area 50 is formed in the corner of the active area 110A. Similarly, FIG. 6 illustrates an embodiment of a Schottky diode structure 100B in which the integrated test area 50 is formed along a side of the main active area 110A.

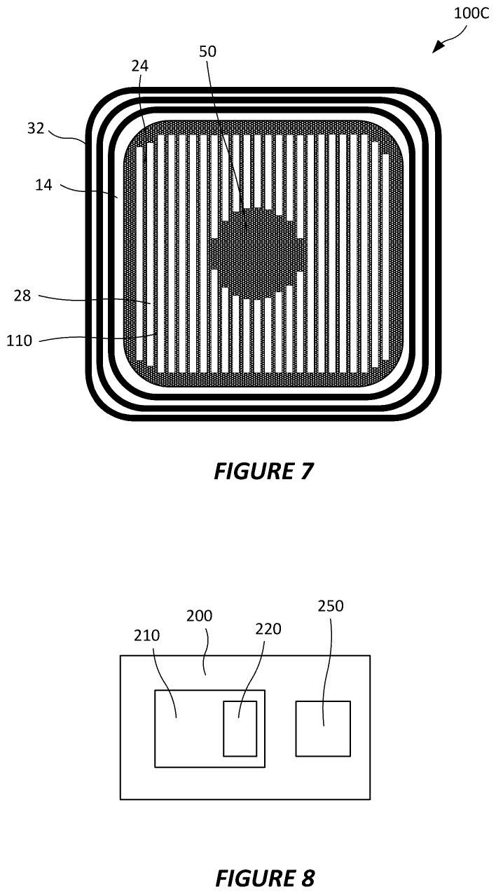

Likewise, although illustrated in FIGS. 3A and 3B as having a generally rectangular shape, it will be appreciated that the integrated test area 50 may have a different shape, such as circular, elliptical, triangular, or any other desired shape. For example, FIG. 7 illustrates a further embodiment of a Schottky diode structure 100C in which the integrated test area 50 has a generally circular shape.

Although described above primarily in the context of a silicon carbide Schottky diode, it will be appreciated that the inventive concepts may be applied in some embodiments to other types of semiconductor devices, such as bipolar junction transistors (BJTs), metal oxide semiconductor field effect transistors (MOSFETs), high electron mobility transistors (HEMTs) and other types of devices. Moreover, it will be appreciated that in some embodiments, the integrated test area 50 may be formed outside the active region of the device.

For example, FIG. 8 illustrates an embodiment of a singulated semiconductor device 200, which may, for example, be a BJT, HEMT, MOSFET or other type of semiconductor device. The semiconductor device includes an active area 210 including an implanted region 220 therein. The implanted region 220 may correspond to a contact region, a channel region or other region of the semiconductor device 200. The device 200 further includes an integrated test area 250 that is outside the active area 210 of the device. The integrated test area 250 may include an implanted region that is formed in the same implantation process used to form the implanted region 220. The integrated test area 250 may have similar dimensions and/or shapes as described above with respect to the integrated test area 250, and in particular may be sized to allow testing of the integrated test area 250 via SIMS analysis.

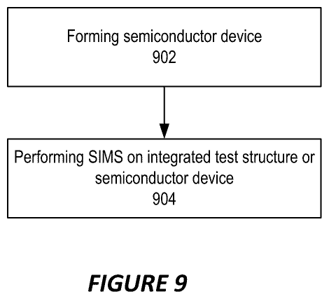

Some embodiments provide a method of testing a semiconductor device. Referring to FIG. 9, a method of testing a semiconductor device is illustrated. The semiconductor device may be a singulated device having a semiconductor layer (14) comprising an active area (110A) and an edge termination area (110B) outside the active area, wherein the semiconductor layer has a first conductivity type, a plurality of implanted regions within the active area at a surface of the semiconductor layer, wherein the plurality of implanted regions have a second conductivity type opposite the first conductivity type, and an integrated test area (50) in the semiconductor layer, wherein the integrated test area comprises an implanted region. The method includes forming the semiconductor device including the integrated test area (block 902), and performing secondary ion mass spectrometry (SIMS) analysis on the integrated test area of the semiconductor device (block 904).

Because SIMS analysis is a destructive test, it will be appreciated that such analysis would normally not be performed on a device during production. However, such a test may be performed, for example, as part of failure analysis on a returned device. Due to the presence of the integrated test structure, it is possible to perform a SIMS analysis on a device as part of a failure analysis to determine, for example, why the device did not exhibit a certain level of performance.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A semiconductor device, comprising:
a semiconductor layer comprising an active area and an edge termination area outside the active area;
a first implanted region within the active area at a surface of the semiconductor layer; and
an integrated test area in the semiconductor layer, wherein the integrated test area comprises a second implanted region in the semiconductor layer.

2. The semiconductor device of claim 1, wherein the integrated test area is within the active area.

3. The semiconductor device of claim 1, wherein the integrated test area is outside the active area.

4. The semiconductor device of claim 1, wherein the semiconductor layer has a first conductivity type and wherein the first implanted region and the second implanted region have a second conductivity type opposite the first conductivity type;

5. The semiconductor device of claim 1, further comprising an anode contact on the semiconductor layer in the active area, wherein the anode contact contacts the integrated test area.

6. The semiconductor device of claim 1, wherein the integrated test area has peripheral dimensions selected to permit a destructive material test to be performed on the semiconductor layer within the integrated test area

7. The semiconductor device of claim 1, wherein the semiconductor layer has a first conductivity type, wherein the active area comprises a first plurality of junction shielding regions in the semiconductor layer, the first plurality of junction shielding regions having a second conductivity type opposite the first conductivity type;
wherein the anode contact contacts the semiconductor layer, the first plurality of junction shielding regions and the integrated test area.

8. The semiconductor device of claim 1, wherein the semiconductor layer has a first conductivity type, and wherein the integrated test areas has the first conductivity type.

9. The semiconductor device of claim 1, wherein the semiconductor layer has a first conductivity type, and wherein the integrated test areas has a second conductivity type opposite the first conductivity type.

10. The semiconductor device of claim 1, wherein the active area has a generally rectangular shape, and wherein the test active area is located near a center of the active area.

11. The semiconductor device of claim 1, wherein the active area has a generally rectangular shape, and wherein the test active area is located near a corner of the active area.

12. The semiconductor device of claim 1, wherein the active area has a generally rectangular shape, and wherein the test area is located near a middle of a side of the active area.

13. The semiconductor device of claim 1, wherein the integrated test area has an area of at least about 2500 μm².

14. The semiconductor device of claim 1, wherein the integrated test area is square in shape.

15. The semiconductor device of claim 14, wherein a side length of the integrated test area is from about 50 μm to about 150 μm.

16. The semiconductor device of claim 1, wherein the semiconductor device comprises a Schottky diode device, a bipolar junction transistor, or a metal-oxide semiconductor device

17. The semiconductor device of claim 1, further comprising:
a metal layer on the semiconductor layer, wherein the metal layer contacts the first implanted region; and
an insulating layer on the second implanted region, wherein the second implanted region is insulated from the metal layer by the insulating layer.

18. The semiconductor device of claim 1, further comprising:
an isolation region in the semiconductor layer, wherein the isolation region surrounds the second implanted region.

19. The semiconductor device of claim 18, wherein the isolation region comprises a trench in the semiconductor layer or a semi-insulating region in the semiconductor layer.

20. A method, comprising:
forming a singulated semiconductor device, wherein the singulated semiconductor device comprises a semiconductor layer comprising an active area, a first implanted region within the active area at a surface of the semiconductor layer, and an integrated test area within the active area, wherein the integrated test area comprises a second implanted region in the semiconductor layer; and
performing secondary ion mass spectrometry (SIMS) analysis on the integrated test area of the singulated semiconductor device.

21. The method of claim 20, wherein the semiconductor layer has as first conductivity type, and wherein the integrated test area has the first conductivity type.

22. The method of claim 20, wherein the semiconductor layer has as first conductivity type, and wherein the integrated test area has a second conductivity type opposite the first conductivity type.

23. The method of claim 20, wherein the integrated test area has peripheral dimensions selected to permit a destructive material test to be performed on the semiconductor layer within the integrated test area

24. The method of claim 20, wherein the semiconductor layer has a first conductivity type and the integrated test region has a second conductivity type opposite the first conductivity type, wherein the active area comprises a first plurality of junction shielding regions in the semiconductor layer, the first plurality of junction shielding regions having the second conductivity type;
wherein the anode contact contacts the semiconductor layer, the first plurality of junction shielding regions and the integrated test area.

25. The method of claim 24, wherein the semiconductor layer comprises an n-type semiconductor material, and wherein the integrated test area comprises a p-type semiconductor material.

26. The method of claim 20, wherein the active area has a generally rectangular shape, and wherein the test active area is located near a center of the active area.

27. The method of claim 20, wherein the active area has a generally rectangular shape, and wherein the test active area is located near a corner of the active area.

28. The method of claim 20, wherein the active area has a generally rectangular shape, and wherein the test area is located near a middle of a side of the active area.

29. The method of claim 20, wherein the integrated test area has an area of at least about 2500 μm².

30. The method of claim 20, wherein the integrated test area is square in shape.

31. The method of claim 30, wherein a side length of the integrated test area is from about 50 μm to about 150 μm.

32. The method of claim 20, wherein the semiconductor device comprises a Schottky diode device, a bipolar junction transistor, or a metal-oxide semiconductor device.

33. The method of claim 20, wherein the integrated test area is outside the active area.

34. The method of claim 20, wherein the SIMS analysis is performed after a failure of the device during operation of the device.

35. The method of claim 20, further comprising:
forming a metal layer on the semiconductor layer, wherein the metal layer contacts the first implanted region; and
forming an insulating layer on the second implanted region, wherein the second implanted region is insulated from the metal layer by the insulating layer.

36. The method of claim 20, further comprising:
forming an isolation region in the semiconductor layer, wherein the isolation region surrounds the second implanted region.

37. The method of claim 36, wherein the isolation region comprises a trench in the semiconductor layer or a semi-insulating region in the semiconductor layer.
